(19) United States
(12) Patent Application Publication
(10) Pub. No.: US 2026/0206310 A1
(43) Pub. Date: Jul. 16, 2026

(54) SEMICONDUCTOR STRUCTURE AND FABRICATION METHOD THEREOF

(71) Applicant: NANYA TECHNOLOGY CORPORATION, New Taipei City (TW)

(72) Inventors: Shih Min Hung, New Taipei City (TW); Ying-Cheng Chuang, New Taipei City (TW)

(73) Assignee: NANYA TECHNOLOGY CORPORATION, New Taipei City (TW)

(21) Appl. No.: 19/023,185

(22) Filed: Jan. 15, 2025

(51) Int. Cl. H10D 84/85; H10D 62/57; H10D 62/83; H10D 62/832; H10D 84/01

(52) U.S. Cl. CPC H10D 84/856; H10D 62/57; H10D 62/83; H10D 62/832; H10D 84/0188

(57) ABSTRACT

A semiconductor structure is provided. The semiconductor structure includes a substrate, a first semiconductor film, a second semiconductor film, a first gate structure and a second gate structure. The substrate includes an N-type semiconductor region and a P-type semiconductor region. The first semiconductor film is formed on a flat top surface of the P-type semiconductor region. The second semiconductor film is formed on a rough top surface of the N-type semiconductor region. The first semiconductor film and the second semiconductor film comprise different materials. The first gate structure is disposed on the first semiconductor film. The second gate structure is disposed on the second semiconductor film.

### BACKGROUND

### Technical Field

The present invention relates to a semiconductor structure and fabrication method thereof

### Description of Related Art

N-type Metal-Oxide-Semiconductor (NMOS) and P-type Metal-Oxide-Semiconductor (PMOS) are foundational technologies in semiconductor devices. NMOS transistors use N-type carriers (electrons), which have high mobility, allowing for faster operation, while PMOS transistors use P-type carriers (holes) and generally have lower mobility, leading to relatively slower switching speeds.

In integrated circuits, it is very common to use PMOS, NMOS, and/or Complementary Metal-Oxide-Semiconductor (CMOS). CMOS technology combines NMOS and PMOS transistors, enabling efficient logic circuits with low power consumption. This complementary structure allows the transistors to alternate their on and off states, significantly reducing energy loss, which is essential for modern digital devices.

### SUMMARY

The present invention provides a semiconductor structure and a fabrication method thereof. The semiconductor structure includes a substrate with a P-type semiconductor region and an N-type semiconductor region, a first semiconductor film on the P-type semiconductor region, and a second semiconductor film on the N-type semiconductor region.

In accordance with some embodiments of the present disclosure, a semiconductor structure includes a substrate, a first semiconductor film, a second semiconductor film, a first gate structure and a second gate structure. The substrate includes an N-type semiconductor region and a P-type semiconductor region. The first semiconductor film is formed on a flat top surface of the P-type semiconductor region. The second semiconductor film is formed on a rough top surface of the N-type semiconductor region. The first semiconductor film and the second semiconductor film comprise different materials. The first gate structure is disposed on the first semiconductor film. The second gate structure is disposed on the second semiconductor film.

In some embodiments, a top surface of the first semiconductor film is coplanar with a top surface of the second semiconductor film.

In some embodiments, a bottom surface of the second semiconductor film is rough, while the top surface of the first semiconductor film, the top surface of the second semiconductor film and a bottom surface of the first semiconductor film are flat.

In some embodiments, the semiconductor structure includes a shallow trench isolation structure embedded in the substrate and disposed between the N-type semiconductor region and the P-type semiconductor region. A top surface of the shallow trench isolation structure is coplanar with a top surface of the first semiconductor film and a top surface of the second semiconductor film.

In some embodiments, a thickness of the second semiconductor film is greater than a thickness of the first semiconductor film.

In accordance with some embodiments of the present disclosure, a fabrication method of a semiconductor structure includes the following steps: forming a first semiconductor material film on a substrate; forming an N-type semiconductor region and a P-type semiconductor region in the substrate; forming a mask layer on the first semiconductor material film above a top surface of the P-type semiconductor region; performing an etching process to remove a portion of the first semiconductor material film, thereby forming a first semiconductor film under the mask layer, wherein a top surface of the N-type semiconductor region is roughened during the etching process, resulting in a roughness of the top surface of the N-type semiconductor region greater than a roughness of the top surface of the P-type semiconductor region; forming a second semiconductor film on the top surface of the N-type semiconductor region, wherein the first semiconductor film and the second semiconductor film comprise different materials; forming a first gate structure on the first semiconductor film; and forming a second gate structure on the second semiconductor film.

In some embodiments, the first semiconductor material film is formed by a chemical vapor deposition process, and the second semiconductor film is formed by an epitaxial process.

In some embodiments, a shallow trench isolation structure is formed in the substrate. The shallow trench isolation structure is located between the N-type semiconductor region and the P-type semiconductor region. The mask layer covers a portion of a top surface of the shallow trench isolation structure.

In some embodiments, the shallow trench isolation structure passes through the fir semiconductor material film.

In some embodiments, a planarization process is performed on the top surface of the shallow trench isolation structure, a top surface of the first semiconductor film and a top surface of the second semiconductor film.

Based on the above, the first semiconductor film may be utilized to enhance carrier mobility, while the second semiconductor film helps to smooth the rough surface of the N-type semiconductor region and can prevent height differences between the first gate structure and the second gate structure formed over the P-type and N-type semiconductor regions, respectively.

### BRIEF DESCRIPTION OF THE DRAWINGS

FIGS. 1A to 1J are schematic cross-sectional views of the manufacturing method of a semiconductor structure of the embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

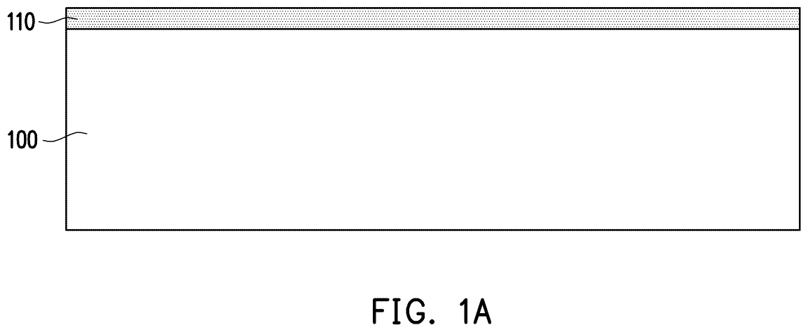

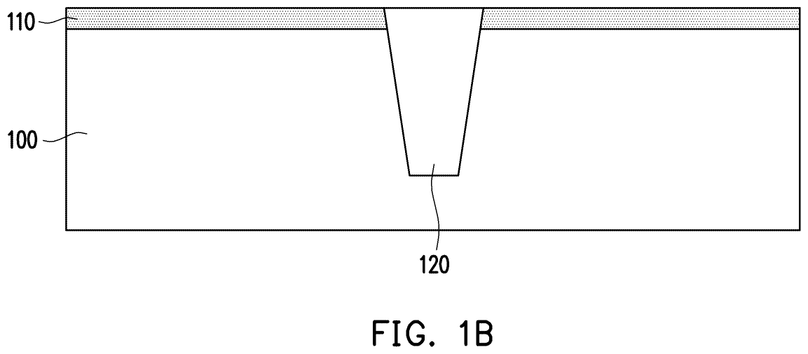

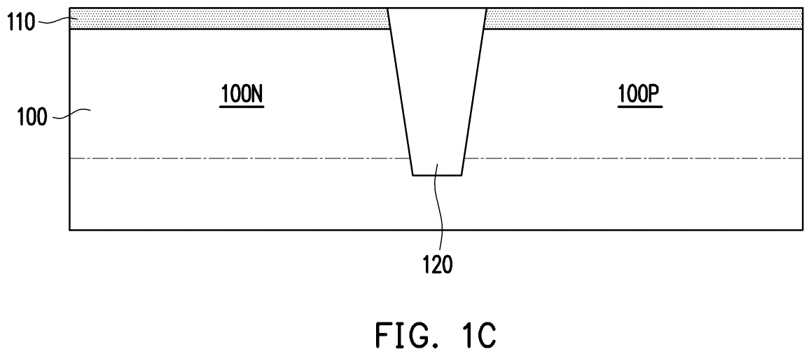

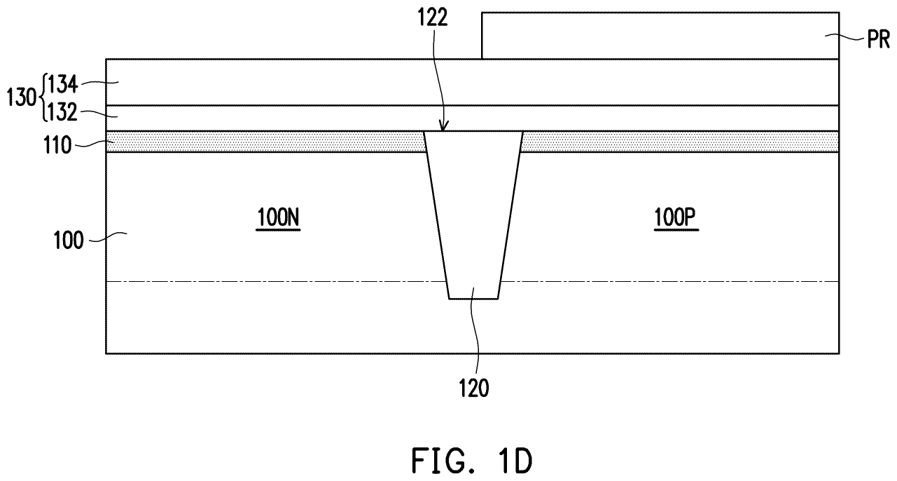

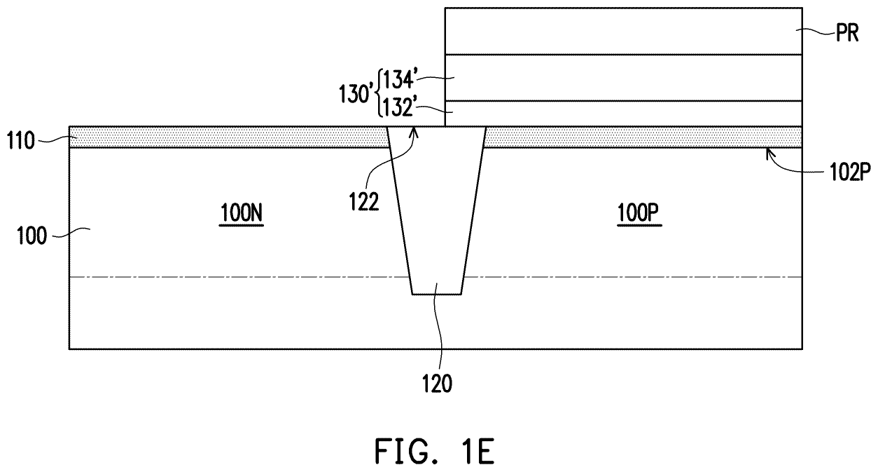

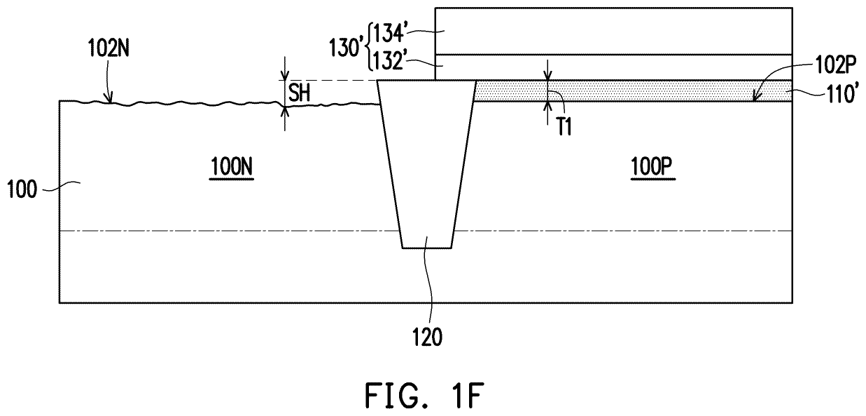

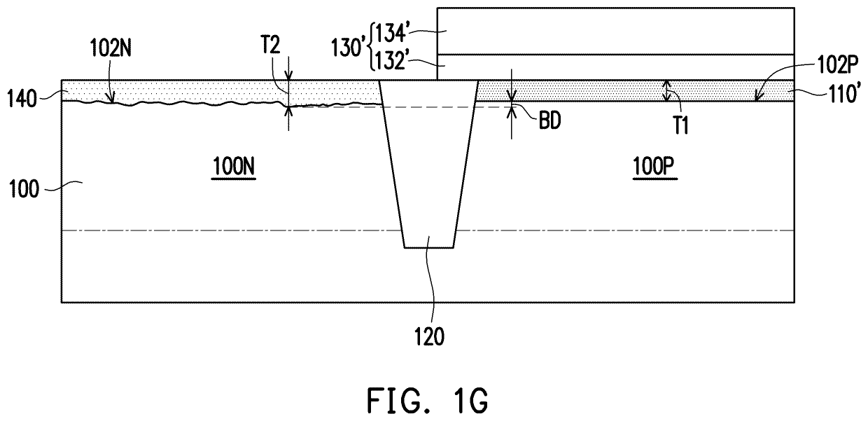

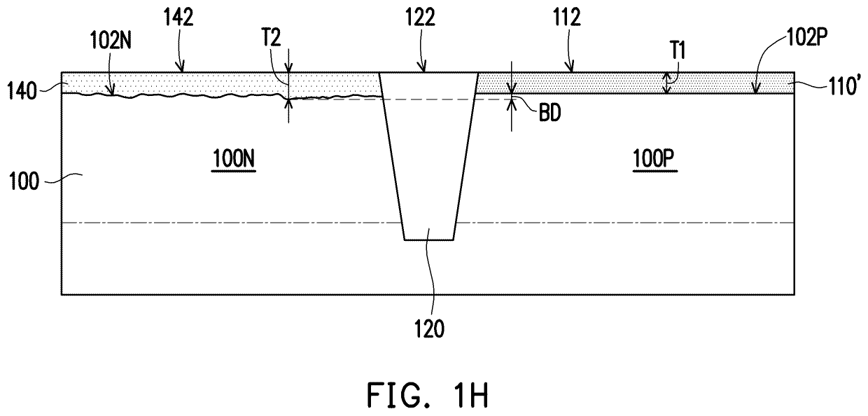

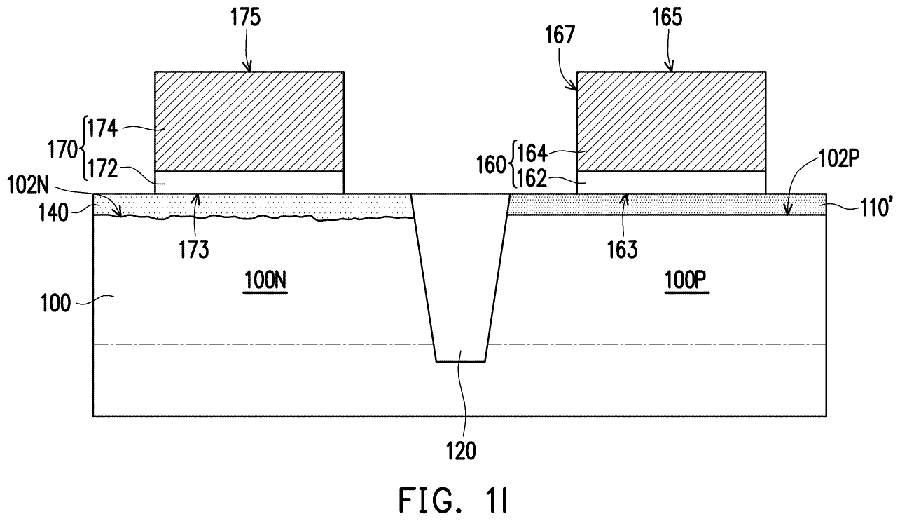

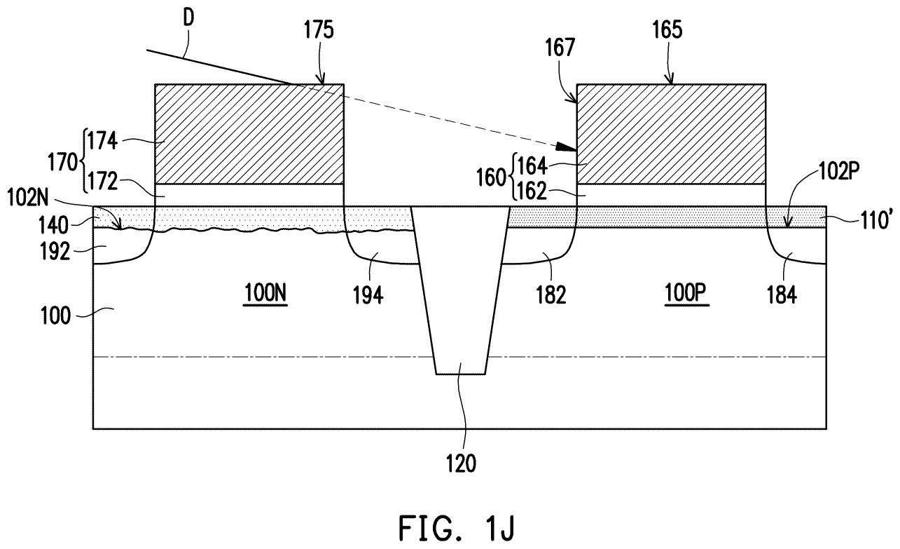

FIGS. 1A to 1J are schematic cross-sectional views of the manufacturing method of the semiconductor structure of the embodiment of the present invention. Referring to FIG. 1A, a substrate 100 is provided. In some embodiments, the substrate 100 may be a semiconductor substrate, such as a bulk semiconductor or the like. The substrate 100 may include an elementary semiconductor including silicon in a single crystal form, a polycrystalline form, or an amorphous form. In some embodiments, the substrate 100 may be an N-type or P-type semiconductor substrate; however, this disclosure is not limited thereto.

A first semiconductor material film 110 is formed on the substrate 100. In some embodiments, the first semiconductor material film 110 includes SiGe or other suitable materials. In some embodiments, the first semiconductor material film 110 is formed by a chemical vapor deposition process or other suitable process.

By utilizing SiGe (i.e. the first semiconductor material film 110) to reduce resistance and leveraging the larger volume of Ge to expand or compress the transistor channel, electron and hole mobility can be enhanced. This enables transistors to operate at lower voltages with faster switching speeds while minimizing leakage current. In certain embodiments, an annealing process is performed on the first semiconductor material film 110 after its deposition, with the annealing temperature is less than 800 degrees Celsius.

Referring to FIG. 1B, a shallow trench isolation (STI) structure 120 is formed in the substrate 100. In some embodiments, an opening is first formed in the substrate 100, followed by the filling of the opening with an insulating material to create the STI structure 120. The insulating material may include oxides, such as silicon dioxide, or other suitable materials. In certain embodiments, the STI structure 120 is formed after the first semiconductor material film 110, resulting in the STI structure 120 extending through the first semiconductor material film 110.

Referring to FIG. 1C, an N-type semiconductor region 100N and a P-type semiconductor region 100P are formed in the substrate 100. For example, the N-type semiconductor region 100N and the P-type semiconductor region 100P are formed through one or more doping processes. In some embodiments, the doping process includes ion implantation or other process.

The STI structure 120 is embedded in the substrate 100 and located between the N-type semiconductor region 100N and the P-type semiconductor region 100P. In other words, the STI structure 120 is used to separate the N-type semiconductor region 100N from the P-type semiconductor region 100P.

In this embodiment, the STI structure 120 is formed first, followed by the formation of the N-type semiconductor region 100N and the P-type semiconductor region 100P in the substrate 100; however, this disclosure is not limited to this sequence. In other embodiments, the N-type semiconductor region 100N and the P-type semiconductor region 100P may be formed first through one or more doping processes, after which the STI structure 120 is formed between the N-type semiconductor region 100N and the P-type semiconductor region 100P.

Referring to FIG. 1D, a mask material layer 130 is formed over the first semiconductor material film 110. The mask material layer 130 extends across the N-type semiconductor region 100N, the P-type semiconductor region 100P, and the STI structure 120. The mask material layer 130 is in contact with the top surfaces of the first semiconductor material film 110 and the STI structure 120. The mask material layer 130 may have a single-layer or multi-layer structure. In this embodiment, the mask material layer 130 features a multi-layer structure that includes a first layer 132 at the bottom and a second layer 134 at the top. The first layer 132 and the second layer 134 comprise different materials. In some embodiments, the first layer 132 includes an oxide such as silicon oxide, while the second layer 134 includes a nitride such as silicon nitride. However, the first layer 132 and the second layer 134 may also include other suitable materials. In some embodiments, the first layer 132 may also be referred to as an adhesion layer, which serves to enhance the adhesion between the mask material layer 130 and the first semiconductor material film 110.

A patterned photoresist layer PR is formed above the mask material layer 130. The patterned photoresist layer PR is located over the P-type semiconductor region 100P. In some embodiments, the patterned photoresist layer PR overlaps the P-type semiconductor region 100P while not overlapping the N-type semiconductor region 100N. In certain embodiments, a sidewall of the patterned photoresist layer PR is directly above a top surface 122 of the STI structure 120.

Referring to FIG. 1E, using the patterned photoresist layer PR as a mask, the mask material layer 130 is patterned through dry etching or wet etching to obtain a mask layer 130′. The mask layer 130′ is formed on the first semiconductor material film 110 above the top surface 102P of the P-type semiconductor region 100P. In some embodiments, the etching process is performed until the first semiconductor material film 110 over the N-type semiconductor region 100N is exposed. In certain embodiments, the mask layer 130′ covers a portion of the top surface 122 of the STI structure 120, and another portion of the top surface 122 of the STI structure 120 is exposed after the etching process. In some embodiments, the exposed portion of the top surface of the STI structure 120 may be damaged during the etching process, but the disclosure is not limited thereto.

In some embodiments, the mask layer 130′ has a multi-layer structure that includes a first layer 132′ and a second layer 134′, but the disclosure is not limited thereto. In other embodiments, the mask layer 130′ may have a single-layer structure.

Next, an etching process is performed to remove a portion of the first semiconductor material film 110 above the N-type semiconductor region 100N, as shown in FIG. 1F. In some embodiments, a portion of a sidewall of the STI structure 120 is also exposed after the etching process. The remaining portion of the first semiconductor material film 110 forms a first semiconductor film 110′ beneath the mask layer 130′. In some embodiments, the etching process for the mask layer 130′ differs from the etching process for the first semiconductor material film 110, for example, by using different etchants.

Referring to FIG. 1F, the top surface 102N of the N-type semiconductor region 100N is roughened during the etching process, resulting in a roughness of the top surface 102N greater than a roughness of the top surface 102P of the P-type semiconductor region 100P.

The top surface 102N exhibits a rough surface with irregularities, and there is a height difference SH between the lowest point of this rough surface and the top surface of the first semiconductor film 110′. In some embodiments, the height difference SH is greater than the thickness T1 of the first semiconductor film 110′.

In some embodiments, after forming the first semiconductor film 110′, the patterned photoresist layer PR is removed. For example, the patterned photoresist layer PR may be removed using a stripping process.

Referring to FIG. 1G, a second semiconductor film 140 is formed on the top surface 102N of the N-type semiconductor region 100N. In some embodiments, the method for forming the second semiconductor film 140 includes an epitaxial process, and the second semiconductor film 140 is formed only on the exposed portion of the substrate 100 (i.e., the top surface 102N of the N-type semiconductor region 100N), without forming on the STI structure 120 and the mask layer 130′. In some embodiments, the second semiconductor film 140 is formed using a low-temperature epitaxial growth technique to minimize damage to the first semiconductor film 110′ caused by the epitaxial process. In certain embodiments, the temperature for forming the second semiconductor film 140 is below 800° C., for instance, ranging from approximately 450° C. to 650° C. In some embodiments, the process gases used to form the second semiconductor film 140 include SiH₄ or Si₂H₆, and may also include N₂ gas.

In some embodiments, the first semiconductor film 110′ and the second semiconductor film 140 comprise different materials. For example, the first semiconductor film 110′ may include a SiGe alloy, while the second semiconductor film 140 may consist of N-doped silicon. In certain embodiments, the N-type dopants in the second semiconductor film 140 include pentavalent elements (such as phosphorus, arsenic, tellurium, etc.). The second semiconductor film 140 helps to smooth the rough top surface 102N, thereby enhancing the performance of the NMOS transistor. In this embodiment, the bottom surface of the second semiconductor film 140 is rough, while the bottom surface of the first semiconductor film 110′ is flat.

In some embodiments, due to the roughness of the top surface 102N, which includes recessed areas, the thickness T2 of the second semiconductor film 140 (measured from the lowest point of the rough bottom surface to the flat top surface) is greater than the thickness T1 of the first semiconductor film 110′.

Referring to FIG. 1H, the mask layer 130′ is removed. In some embodiments, the method for removing the mask layer 130′ includes wet etching, dry stripping, or other suitable techniques. In certain embodiments, after removing the mask layer 130′, a planarization process is performed on the top surface 122 of the STI structure 120, the top surface 112 of the first semiconductor film 110′, and the top surface 142 of the second semiconductor film 140. For example, planarization may be achieved through a chemical mechanical polishing (CMP) process. In some embodiments, the top surface 112 of the first semiconductor film 110′, the top surface 142 of the second semiconductor film 140, and the top surface 122 of the STI structure 120 are flat and coplanar.

Referring to FIG. 1I, a first gate structure 160 is disposed on the first semiconductor film 110′, and a second gate structure 170 is disposed on the second semiconductor film 140. The first gate structure 160 includes a first metal gate 164 and a first gate insulation layer 162, while the second gate structure 170 includes a second metal gate 174 and a second gate insulation layer 172. In some embodiments, the first metal gate 164 and the second metal gate 174 may be composed of the same or different materials, and the first gate insulation layer 162 and the second gate insulation layer 172 may be composed of the same or different materials. This disclosure does not limit the specific structure or layer count of the first gate structure 160 and the second gate structure 170. In other words, each of the first gate structure 160 and the second gate structure 170 may include additional structures, such as spacers (not shown) and/or cap layers (not shown).

Without the presence of the second semiconductor film 140, the bottom surface 163 of t he first gate structure 160 and the bottom surface 173 of the second gate structure 170 would be at different heights. In this embodiment, the second semiconductor film 140 enables the bottom surface 163 of the first gate structure 160 and the bottom surface 173 of the second gate structure 170 to be positioned at substantially the same height. In certain embodiments, the top surface 165 of the first gate structure 160 and the top surface 175 of the second gate structure 170 are also aligned. This alignment reduces the likelihood of damage to the sidewall 167 of the first gate structure 160 during subsequent ion implantation processes. As shown in FIG. 1J, during the ion implantation process, the first gate structure 160 and the second gate structure 170, being at the same height, allow the second gate structure 170 to shield the first gate structure 160 from particles or ions moving in the direction of arrow D, preventing such particles or ions from impacting the first gate structure 160. Without the second semiconductor film 140, the top surface 175 of the second gate structure 170 would be lower than the top surface 165 of the first gate structure 160, potentially resulting in the inability of the second gate structure 170 to shield the first gate structure 160 from particles or ions moving along arrow D, thereby increasing the risk of damage to the sidewall 167 of the first gate structure 160.

It should be noted that arrow D in FIG. 1J does not indicate that the ion implantation process is conducted solely in the direction of arrow D. In practice, the ion implantation process may occur along various directions, with arrow D representing particles or ions that are scattered or reflected during the ion implantation process.

In this embodiment, an ion implantation process is performed on the first semiconductor film 110′ to form two first source/drain regions 182 and 184 on opposite sides of the first gate structure 160. In some embodiments, the first source/drain regions 182 and 184 extend from the first semiconductor film 110′ into the P-type semiconductor region 100P. In certain embodiments, an ion implantation process is performed on the second semiconductor film 140 to form two second source/drain regions 192 and 194 respectively located on opposite sides of the second gate structure 170. In some embodiments, the second source/drain regions 192 and 194 extend from the second semiconductor film 140 into the N-type semiconductor region 100N. The ion implantation process used to form the first source/drain regions 182 and 184 may be the same as or different from the ion implantation process used to form the second source/drain regions 192 and 194.

In this embodiment, the PMOS transistor includes the P-type semiconductor region 100P, the first semiconductor film 110′, the first gate structure 160, and the first source/drain regions 182 and 184, while the NMOS transistor includes the N-type semiconductor region 100N, the second semiconductor film 140, the second gate structure 170, and the second source/drain regions 192 and 194. The PMOS and NMOS transistors may operate independently or together as part of a CMOS configuration.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate comprising an N-type semiconductor region and a P-type semiconductor region;
a first semiconductor film, formed on a flat top surface of the P-type semiconductor region;
a second semiconductor film, formed on a rough top surface of the N-type semiconductor region, wherein the first semiconductor film and the second semiconductor film comprise different materials;
a first gate structure, disposed on the first semiconductor film; and
a second gate structure, disposed on the second semiconductor film.

2. The semiconductor structure of claim 1, wherein a top surface of the first semiconductor film is coplanar with a top surface of the second semiconductor film.

3. The semiconductor structure of claim 2, wherein a bottom surface of the second semiconductor film is rough, while the top surface of the first semiconductor film, the top surface of the second semiconductor film and a bottom surface of the first semiconductor film are flat.

4. The semiconductor structure of claim 1, further comprising:
a shallow trench isolation structure, embedded in the substrate and disposed between the N-type semiconductor region and the P-type semiconductor region, wherein a top surface of the shallow trench isolation structure is coplanar with a top surface of the first semiconductor film and a top surface of the second semiconductor film.

5. The semiconductor structure of claim 1, wherein a thickness of the second semiconductor film is greater than a thickness of the first semiconductor film.

6. A fabrication method of a semiconductor structure, comprising:
forming a first semiconductor material film on a substrate;
forming an N-type semiconductor region and a P-type semiconductor region in the substrate;
forming a mask layer on the first semiconductor material film above a top surface of the P-type semiconductor region;
performing an etching process to remove a portion of the first semiconductor material film, thereby forming a first semiconductor film under the mask layer, wherein a top surface of the N-type semiconductor region is roughened during the etching process, resulting in a roughness of the top surface of the N-type semiconductor region greater than a roughness of the top surface of the P-type semiconductor region;
forming a second semiconductor film on the top surface of the N-type semiconductor region, wherein the first semiconductor film and the second semiconductor film comprise different materials;
forming a first gate structure on the first semiconductor film; and
forming a second gate structure on the second semiconductor film.

7. The fabrication method of claim 6, wherein the first semiconductor material film is formed by a chemical vapor deposition process, and the second semiconductor film is formed by an epitaxial process.

8. The fabrication method of claim 6, further comprising:
forming a shallow trench isolation structure in the substrate, wherein the shallow trench isolation structure is located between the N-type semiconductor region and the P-type semiconductor region, wherein the mask layer covers a portion of a top surface of the shallow trench isolation structure.

9. The fabrication method of claim 8, wherein the shallow trench isolation structure is extending through the first semiconductor material film.

10. The fabrication method of claim 8, further comprising:
performing a planarization process on the top surface of the shallow trench isolation structure, a top surface of the first semiconductor film and a top surface of the second semiconductor film.
